(19) United States
(12) Patent Application Publication
(10) Pub. No.: US 2008/0242114 A1
(43) Pub. Date: Oct. 2, 2008

(54) THERMAL ANNEAL METHOD FOR A HIGH-K DIELECTRIC

(75) Inventors: Manuel Quevedo-Lopez, Richardson, TX (US); Husam Alshareef, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/695,324

(22) Filed: Apr. 2, 2007

(51) Int. Cl. H01L 21/31

(52) U.S. Cl. 438/785; 257/E21.24

(57) ABSTRACT

A method of manufacturing a semiconductor device is provided. In one embodiment, the method provides for the formation, over a substrate, of a dielectric layer having a high dielectric constant. This dielectric layer may be exposed to a nitrogen plasma after which it may be annealed in a hydrogen containing ambient.

### TECHNICAL FIELD OF THE INVENTION

The invention is directed, in general, to the manufacture of a semiconductor device and, more specifically, to a method of processing a dielectric layer having a high dielectric constant.

### BACKGROUND OF THE INVENTION

In order to facilitate the scaling of semiconductor components, it has become necessary to reduce the thickness of component dielectric layers. For this reason, high dielectric constant materials are frequently used as the gate dielectric in metal oxide semiconductor (MOS) transistor devices.

As is frequently the case, the solution of one problem brings its own new set of problems. Utilizing known processes, high dielectric constant materials suffer from crystallization at relatively low temperatures. In the case of hafnium based high dielectric constant materials, crystallization results in degraded reliability. Currently, in such cases, nitrogen is incorporated into the high dielectric constant materials to increase crystallization temperature and improve the electrical performance of the related device. However, this solution also degrades certain aspects of the device performance, such as mobility.

Accordingly, what is needed in the art is a process that will permit the use of high dielectric constant material layers without degrading electrical performance.

### SUMMARY OF THE INVENTION

To address the above-discussed deficiencies of the prior art, a method of manufacturing a semiconductor device is described herein. In one embodiment, the method provides for the formation, over a substrate, of a dielectric layer having a high dielectric constant. This dielectric layer may be exposed to a nitrogen plasma after which it may be annealed in a hydrogen containing ambient.

Another embodiment for the manufacture of a semiconductor device using the method described herein provides for a gate dielectric layer having a high dielectric constant to be formed over a substrate. The dielectric layer, in this embodiment, is exposed to a nitrogen containing plasma and then annealed in a hydrogen containing ambient. A layer of gate electrode material may then be formed over the layer of gate dielectric material including the gate dielectric layer, after which the layer of gate dielectric material and layer of gate electrode material are patterned to form a gate structure. Source/drain regions could then be formed in the substrate proximate the gate structure.

### BRIEF DESCRIPTION OF THE DRAWINGS

For a more complete understanding of the invention, reference is now made to the following descriptions taken in conjunction with the accompanying drawings, in which:

FIG. 1 illustrates a semiconductor device at an initial stage of manufacture utilizing the method disclosed herein;

FIG. 2 illustrates a plasma nitridation of the layer of gate dielectric material shown on the device in FIG. 1;

FIG. 3 illustrates an anneal of the device shown in FIG. 2 after plasma nitridation of the gate dielectric material;

FIG. 4 illustrates the device shown in FIG. 3 after a layer of gate electrode material is formed over the gate dielectric material layer;

FIG. 5 illustrates the device shown in FIG. 4 after patterning the layer of gate dielectric material and the layer of gate electrode material;

FIG. 6 illustrates a cross-sectional view of the device shown in FIG. 5 after forming gate sidewall spacers and source/drain regions; and

FIG. 7 illustrates an integrated circuit incorporating devices constructed in accordance with the present disclosure.

### DETAILED DESCRIPTION

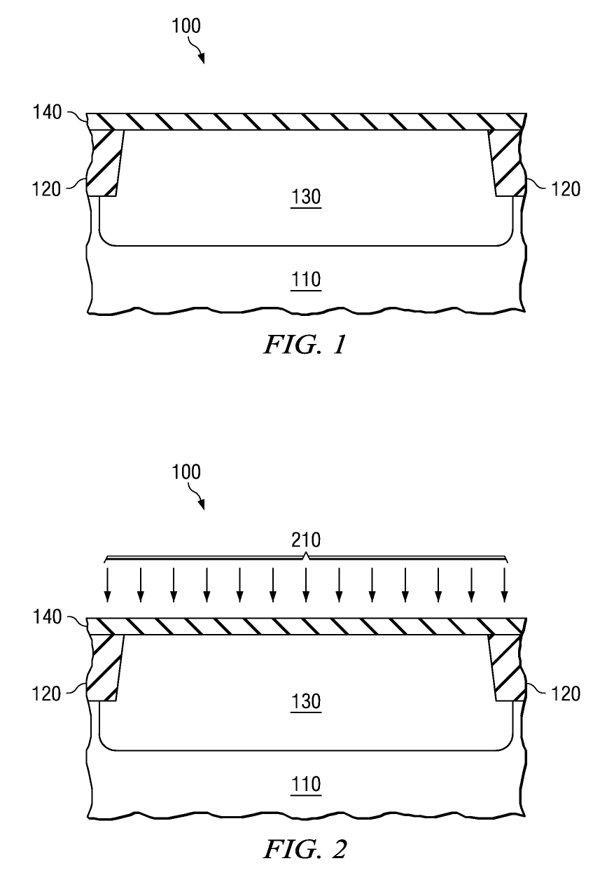

FIGS. 1-6 illustrate views showing one embodiment of a method for manufacturing a semiconductor device 100. FIG. 1 illustrates the device 100 at an initial stage of manufacture wherein the method disclosed herein is used in the manufacturing process. The device 100 initially includes a substrate 110. The substrate 110 may, in one embodiment, be any layer located in the device 100, including a wafer itself or a layer located above the wafer (e.g., epitaxial layer). In the embodiment illustrated in FIG. 1, the substrate 110 is a P-type substrate; however, one skilled in the art understands that the substrate 110 could be an N-type substrate without departing from the scope of the present disclosure. In such a case, each of the dopant types described throughout the remainder of this document could be reversed. For clarity, no further reference to this opposite scheme will be discussed.

Located within the substrate 110 are isolation regions 120 (e.g., shallow trench isolation regions in the embodiment shown). The isolation regions 120 isolate the device 100 from other devices located proximate thereto. As those skilled in the art will understand the various steps used to form these isolation regions 120, no further detail will be given.

Formed within the substrate 110 is a well region 130. The well region 130, in light of the P-type semiconductor substrate 110, would more than likely contain an N-type dopant. For example, the well region 130 would likely be doped with an N-type dopant dose ranging from about 1E13 atoms/cm² to about 1E14 atoms/cm² and at an energy ranging from about 100 keV to about 500 keV. This results in the well region 130 having a peak dopant concentration ranging from about 5E17 atoms/cm³ to about 1E19 atoms/cm³. However, if the device 100 were configured as a P-type metal oxide semiconductor (PMOS) device the well region 130 would include a P-type dopant.

Located over the substrate 110 is a layer of gate dielectric material 140. In this embodiment, the gate dielectric material 140 has a high dielectric constant, referred to by those skilled in the pertinent art as a high-K dielectric. The terms high dielectric constant and high-K dielectric, as used herein, mean a dielectric having a dielectric constant exceeding the dielectric constant of silicon dioxide. The illustrated gate dielectric material 140 can be any one of a number of high-K dielectric materials and be within the scope of this disclosure. Such materials include a variety of hafnium and zirconium silicates and their various oxides. In one embodiment, the high-k dielectric material comprises HfSiO, however in other embodiments the high-k dielectric material might comprise HfO₂, HfAlO or HfLaO. In the embodiment illustrated in FIG. 1, the high-K dielectric gate material 140 may be, for example, Hf based with a thickness ranging from about 1.5 nm to about 5 nm.

A number of different manufacturing techniques can be used to form the layer of gate dielectric material 140. For example, the gate dielectric material 140 may be either grown or deposited. Additionally, the growth or deposition steps may require a significant number of different temperatures, pressures, gasses, flow rates, etc. Such techniques are within the scope of understanding of a person skilled in the pertinent art and are not discussed herein.

FIG. 2 illustrates the plasma nitridation of the layer of gate dielectric material 140 shown in FIG. 1. In one embodiment, following deposition, the gate dielectric material 140 is exposed to a nitrogen containing plasma 210. The nitrogen concentration in the plasma may range from about 10% to 25% with the balance comprising a noble gas, such as helium or argon. The gas composition of the plasma may, for example, be about 75% helium and about 25% nitrogen at a pressure of about 20 to about 80 mTorr. Nevertheless, this illustrates but one embodiment.

One embodiment of the method disclosed herein provides for annealing the gate dielectric material 140 in an inert ambient before exposing it to a nitrogen containing plasma 210. In another embodiment, following an anneal of the gate dielectric material 140 in an inert ambient, it is annealed again in an oxidizing ambient, both of which occur before being exposed to the nitrogen containing plasma 210. Those skilled in the art understand that various temperatures, pressures, and materials are used to perform these anneals. For example, the anneals can be performed at temperatures ranging from about 600° C. to about 1200° C.; pressures ranging from about 1 torr to about 760 torr; and a gas flow from about 1 sccm to about 150 sccm. When annealed in an inert ambient, N₂ or Ar may be used as the inert gas. When annealed in an oxidizing ambient, one of O₂, NO, N₂O, or O₃ may be used for oxidation. When performed before exposing the gate dielectric material 140 to the nitrogen containing plasma 210, the anneals can be used to optimize the incorporation of nitrogen in the high-K gate dielectric material 140. Other benefits include film densification and the elimination of carbon.

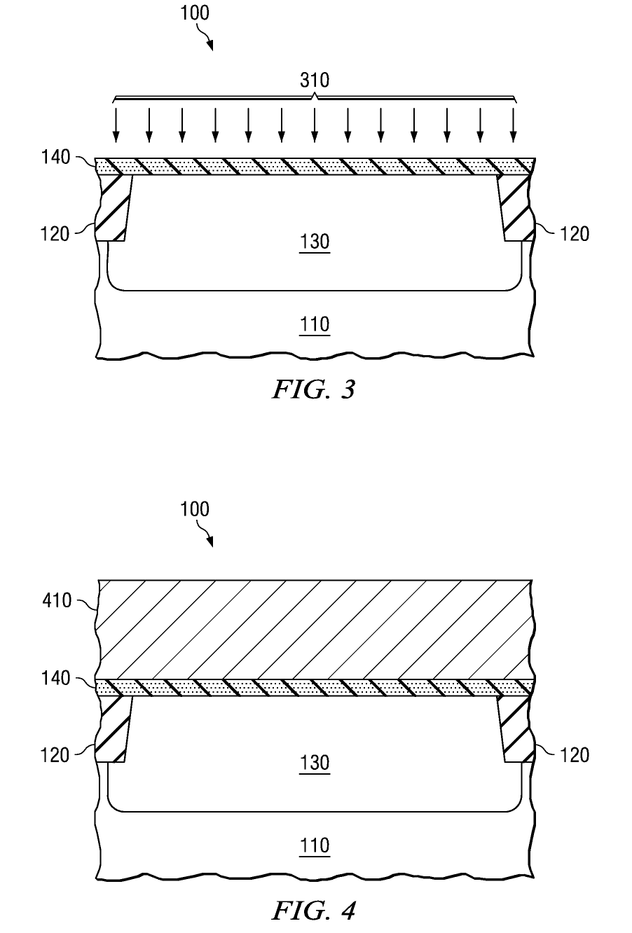

FIG. 3 illustrates an anneal 310 of the device 100 shown in FIG. 2 after plasma nitridation 210 of the gate dielectric material 140. Following plasma nitridation 210, the high-K gate dielectric material 140 is annealed 310 in an oxygen reducing hydrogen containing ambient. In one embodiment the hydrogen containing ambient comprises NH₃. The hydrogen in the ambient may also be a hydrogen isotope. The anneal can be diluted with an inert gas to permit, for example, control of nitrogen when NH₃, or another appropriate gas, is used. In one embodiment the anneal 310 is performed at a temperature of about 700° C. for about sixty seconds. In another embodiment the anneal 310 is performed at a temperature in excess of about 950° C., which embodiment allows the reflow of an interfacial silicon dioxide layer to provide better interface quality.

FIG. 4 illustrates the device 100 shown in FIG. 3 after a layer of gate electrode material 410 is formed over the layer of gate dielectric material 140. The layer of gate electrode material 410 may comprise standard polysilicon, although other embodiments can provide for the gate electrode material 410, or at least a portion thereof, to be amorphous polysilicon. Amorphous polysilicon may be particularly useful when a substantially planar upper surface of the layer of gate electrode material 410 is desired. Other embodiments may also exist wherein the layer of gate electrode material 410 comprises a metal or metal silicide.

The deposition conditions for the layer of gate electrode material 410 may vary, however, if the layer of gate electrode material 410 were to comprise standard polysilicon, the layer of polysilicon material could be deposited using a pressure ranging from about 100 torr to about 300 torr, a temperature ranging from about 620° C. to about 700° C., and a SiH₄ gas flow ranging from about 50 sccm to about 150 sccm. If, however, amorphous polysilicon were desired, the layer of amorphous polysilicon material could be deposited using a pressure ranging from about 100 torr to about 300 torr, a temperature ranging from about 450° C. to about 550° C., and a SiH₄ gas flow ranging from about 100 sccm to about 300 sccm. In any instance, the layer of gate dielectric material 410 may have a thickness ranging from about 15 nm to about 150 nm, among others.

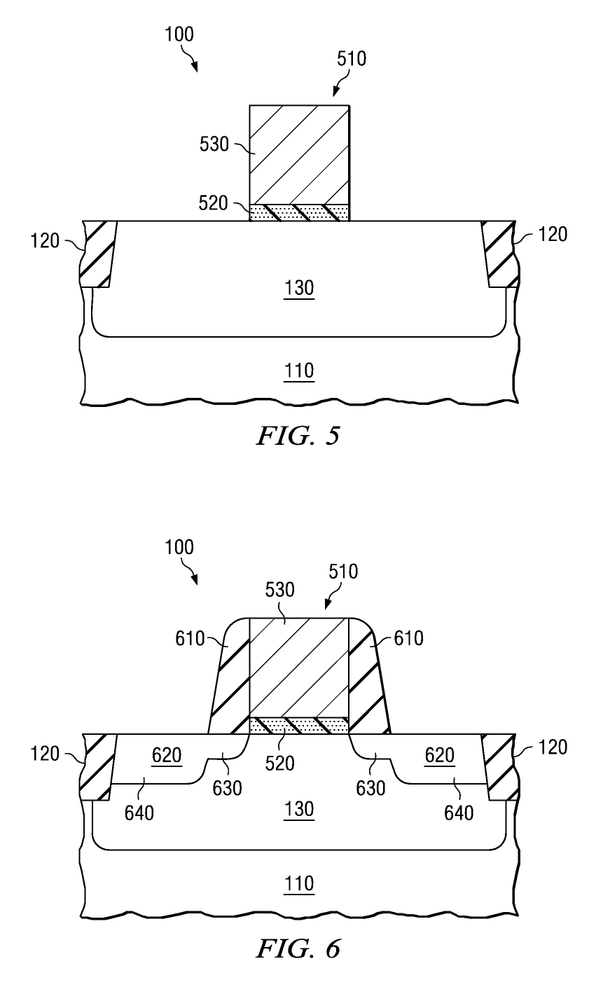

FIG. 5 illustrates the device 100 shown in FIG. 4 after patterning the layer of gate dielectric material 140 and the layer of gate electrode material 410. The result is a gate structure 510 containing a gate dielectric 520 and gate electrode 530. As the steps required for patterning one or more layers is known to those skilled in the art, no further details will be given.

FIG. 6 illustrates a cross-sectional view of the device shown in FIG. 5 after performing various subsequent processing steps. Utilizing processes and procedures known to those skilled in the art, source/drain implants 640 are formed within the substrate 110. Generally the source/drain implants 640 have a peak dopant concentration ranging from about 1E18 atoms/cm³ to about 1E21 atoms/cm³. Also, the source/drain implants 640 should typically have a dopant type opposite to that of the well region 130 they are located within. Accordingly, in the illustrated embodiment, the source/drain implants 640 may be doped with a P-type dopant. Similarly, extension implants 630 are formed within the substrate 110. The extension implants 630 may be conventionally formed and generally have a peak dopant concentration ranging from about 1E19 atoms/cm³ to about 2E20 atoms/cm³. As is standard in the industry, the extension implants 630 also have a dopant type opposite to that of the well region 130 they are located within. Accordingly, the extension implants 630 are doped with an N-type dopant since the well region 130 in the illustrated embodiment has a P-type dopant. The extension implants 630 and source/drain implants 640 may collectively form the source/drain regions 620.

The gate sidewall spacers 610 may be conventionally formed utilizing processes and procedures known to those skilled in the art. Often the gate sidewall spacers 610 comprise a chemical vapor deposition (CVD) oxide and/or nitride material that has been anisotropically etched. In other embodiments, however, the gate sidewall spacers may comprise any one or a collection of L-shaped sidewall spacers.

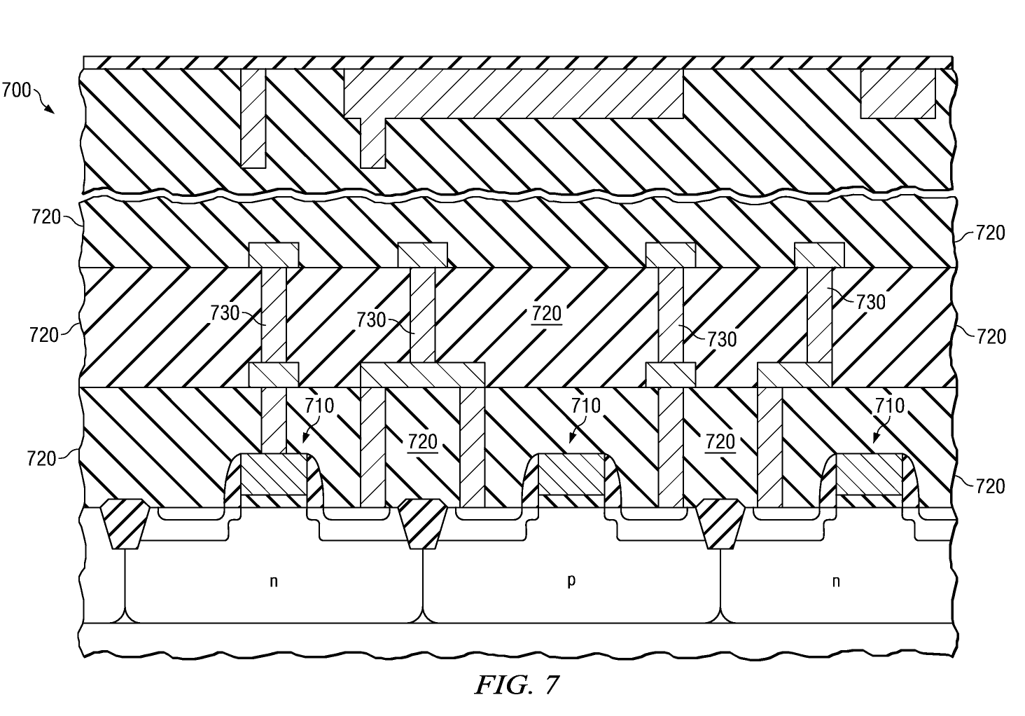

FIG. 7 illustrates an integrated circuit 700 incorporating devices 710 constructed in accordance with the present disclosure. The integrated circuit 700 may include devices, such as transistors used to form CMOS devices, BiCMOS devices, Bipolar devices, as well as capacitors or other types of devices. The integrated circuit 700 may also include passive devices, such as inductors or resistors, or it may include optical devices or optoelectronic devices. Those skilled in the art are familiar with these various types of devices and their manufacture. In the particular embodiment illustrated in FIG. 7, the integrated circuit 700 includes devices 710 having gate dielectric layers located therein, wherein the gate dielectric layers may, for example, be constructed in the manner herein described. Additionally, interconnect structures 730 are located within interlevel dielectric layers 720 to interconnect various devices, thus, forming the operational integrated circuit 700.

Those skilled in the art to which the present disclosure relates will appreciate that other and further additions, deletions, substitutions and modifications may be made to the described embodiments without departing from the disclosure's scope.

What is claimed is:

1. A method of manufacturing a semiconductor device, comprising:
forming a dielectric layer having a high dielectric constant over a substrate;
exposing said dielectric layer to a nitrogen plasma; and
annealing said dielectric layer in a hydrogen containing ambient after said exposing.

2. The method as recited in claim 1 further including subjecting said dielectric layer to a first additional anneal in an inert ambient before exposing said dielectric layer to a nitrogen plasma.

3. The method as recited in claim 2 further including subjecting said dielectric layer to a second additional anneal in an oxidizing ambient after said first additional anneal and before exposing said dielectric layer to a nitrogen plasma.

4. The method as recited in claim 1 wherein said dielectric layer is a gate dielectric.

5. The method as recited in claim 1 wherein said hydrogen containing ambient comprises NH₃.

6. The method as recited in claim 1 wherein said dielectric layer comprises a material selected from the group consisting of:
HfSiO;
HfO₂;
HfAlO; and
HfLaO.

7. The method as recited in claim 1 wherein said hydrogen containing ambient is diluted with an inert gas.

8. The method as recited in claim 1 wherein said hydrogen containing ambient includes a hydrogen isotope.

9. The method as recited in claim 1 wherein said dielectric layer is annealed in said hydrogen containing ambient at a temperature greater than about 950 degrees centigrade.

10. A method of manufacturing a semiconductor device, comprising:
forming a layer of gate dielectric material over a substrate, including:
forming a dielectric layer having a high dielectric constant over the substrate;
exposing said dielectric layer to a nitrogen plasma; and
annealing said dielectric layer in a hydrogen containing ambient after said exposing; and
forming a layer of gate electrode material over the layer of gate dielectric material;
patterning the layer of gate dielectric material and layer of gate electrode material to form a gate structure; and
forming source/drain regions in the substrate proximate the gate structure.

11. The method as recited in claim 10 further including subjecting said dielectric layer to a first additional anneal in an inert ambient before exposing said dielectric layer to a nitrogen plasma.

12. The method as recited in claim 11 further including subjecting said dielectric layer to a second additional anneal in an oxidizing ambient after said first additional anneal and before exposing said dielectric layer to a nitrogen plasma.

13. The method as recited in claim 10 wherein said hydrogen containing ambient comprises NH₃.

14. The method as recited in claim 10 wherein said dielectric layer comprises a material selected from the group consisting of:
HfSiO;
HfO₂;
HfAlO; and
HfLaO.

15. The method as recited in claim 10 wherein said hydrogen containing ambient is diluted with an inert gas.

16. The method as recited in claim 10 wherein said hydrogen containing ambient includes a hydrogen isotope.

17. The method as recited in claim 10 wherein said dielectric layer is annealed in said hydrogen containing ambient at a temperature greater than about 950 degrees centigrade.

18. The method as recited in claim 10 further including forming interlevel dielectric layers over said gate structure, wherein said interlevel dielectric layers have interconnects located therein for contacting said gate structure or said source/drain regions.
